(19) United States
(12) Patent Application Publication
(10) Pub. No.: US 2010/0237901 A1
(43) Pub. Date: Sep. 23, 2010

(54) SEMICONDUCTOR APPARATUS AND DATA OUTPUT METHOD OF THE SAME

(76) Inventor: Dong Uk LEE, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/494,643

(22) Filed: Jun. 30, 2009

(30) Foreign Application Priority Data
Mar. 17, 2009 (KR) 10-2009-0022424

(51) Int. Cl. H03K 19/003; H03K 19/0175

(52) U.S. Cl. 326/30; 326/82

(57) ABSTRACT

A semiconductor apparatus includes a driving control unit configured to receive an enable signal and a data signal. The driving control unit generates a pull-up source signal and a pull-down source signal. The driving control unit is configured to delay the generation timing of the pull-up source signal or the pull-down source signal. The semiconductor apparatus also includes a driver configured to generate a driving data signal by driving the pull-up source signal and the pull-down source signal from the driving control unit. A POD impedance control unit is connected to the output terminal of the driver and has a variable resistance value.

### CROSS-REFERENCES TO RELATED PATENT APPLICATION

The present application claims priority under 35 U.S.C 119(a) to Korean Application No. 10-2009-0022424, filed on Mar. 17, 2009, in the Korean Intellectual Property Office, the disclosure of which is incorporated herein by reference in its entirety as set forth in full.

### BACKGROUND

1. Technical Field

The present invention relates generally to a semiconductor apparatus, and more particularly, to a data output circuit of a semiconductor apparatus.

2. Related Art

Conventional semiconductor integrated circuit systems are provided with several semiconductor apparatuses that each perform individual functions. Each of the semiconductor apparatuses performs an operation of transmitting/receiving data to/from each other through each data transmission line provided among various paths. In these apparatuses, semiconductor memory apparatuses are used as main memories of a microprocessor and operate to transmit/receive data to/from a memory control apparatus. During the transmitting/receiving of data between semiconductor apparatuses that transmit/receive data, signal reflection occurs in the semiconductor integrated circuit system. As a result, the semiconductor apparatuses are provided with an impedance control unit, such as an ODT (On Die Termination) circuit, in order to remove the signal reflection and is configured to minimize noise resulting from the signal reflection.

The interface between the semiconductor apparatuses can have various shapes according to the configuration of the impedance control unit; an SSTL (Stub-Series Termination Logic) type and a POD (Pseudo Open Drain) type are typically used.

FIG. 1 is a diagram schematically showing an SSTL type interface and FIG. 2 is a diagram schematically showing a POD type interface.

Referring to FIG. 1 and FIG. 2, semiconductor memory apparatuses 1-1, 1-2 and memory control apparatuses 2-1, 2-2 respectively, include input buffers 11, 21 and output buffers 12, 22. A transmission line 3 is provided for transmitting data between the semiconductor memory apparatuses 1-1, 1-2 and the memory control apparatuses 2-1, 2-2. The semiconductor apparatuses 1-1, 1-2 and the memory control apparatuses 2-1, 2-2 respectively, include impedance control units 13, 14, 23, 24, in which the impedance control units 13, 23 of the SSTL interface and the impedance control units 14, 24 of the POD interface are configured in different shapes as shown in the figures.

That is, the impedance control units of the SSTL interface (hereafter, SSTL impedance control units 13, 23) are composed of pull-up parts 13-1, 23-1 and pull-down parts 13-2, 23-2. The pull-up parts 13-1, 23-1 and the pull-down parts 13-2, 23-2 include resistance elements R1 to R4 and switching elements SW1 to SW4, respectively. On the contrary, the impedance control units of the POD interface (hereafter, POD impedance control units 14, 24) are composed of only pull-up parts, and include resistance elements R5, R6 and switching elements SW5, SW6, respectively.

The SSTL interface has an advantage of more effectively controlling noise, but has a disadvantage of consuming a large amount of current. The POD interface has been proposed to address the disadvantage of the SSTL interface, and therefore, the current consumption of the POD interface is considerably smaller than the SSTL interface.

FIG. 3 is a diagram schematically showing a configuration of a main driver provided in an output buffer of the semiconductor memory apparatuses of FIG. 1 and FIG. 2. A component, such as a pre-driver, which drives data in response to an output-enable signal and transmits the driven data to a main driver is further provided in an actual output buffer; however, only a main driver is shown herein for the convenience of description. The memory control apparatus is also configured to include an output buffer having a main driver as described above; however, only a main driver of a semiconductor memory apparatus will be described herein.

As shown in the figure, the main driver 12-1 includes an output node ‘Nout’, a first transistor ‘TR1’, and a second transistor ‘TR2’.

The output node ‘Nout’ outputs a driving data signal ‘d_drv’. The first transistor ‘TR1’ is disposed between a first node ‘N1’ and the output node ‘Nout’ and receives a pull-up driving signal ‘pud’ transmitted from a pre-driver at the gate of the transistor ‘TR1’. The second transistor ‘TR2’ is disposed between a second node ‘N2’ and the output node ‘Nout’ and receives a pull-down driving signal ‘pdd’ transmitted from the pre-driver at the gate of the transistor ‘TR2’.

A first inductor ‘L1’ is connected between the supply terminal of an external power supply voltage ‘VDDQ’ and the first node ‘N1’ and a second inductor ‘L2’ is connected between the ground terminal ‘VSS’ and the second node ‘N2’ by embodying inductance formed after package processes. A first capacitor C1 is connected between the supply terminal of the external power supply voltage ‘VDDQ’ and the output node ‘Nout’ and a second capacitor ‘C2’ is connected between the ground terminal ‘VSS’ and the output node ‘Nout’ by embodying capacitance formed after packaging processes.

Semiconductor memory apparatuses in the related art also include a third capacitor ‘C3’ connected between a first node ‘N1’ and a second node ‘N2’ to remove noise generated by inductance and capacitance formed due to a packaging process in the main driver 12-1 of the output buffer 12. Noise of the main driver 12-1 could be considerably reduced by the inclusion of the third capacitor ‘C3’.

However, in this configuration, when the first transistor ‘TR1’ and the second transistor ‘TR2’ of the main driver ‘12-1’ are simultaneously turned on, a current path passing through the first inductor ‘L1’, the first transistor ‘TR1’, the second transistor ‘TR2’, and the second inductor ‘L2’ is formed, generating a significantly large amount of noise. When the main driver 12-1 is activated, the pull-up driving signal ‘pud’ and the pull-down signal ‘pdd’ transmitted from the pre-driver have opposite phases. However, making the level transition timings of the signals coincide with each other is extremely difficult. Therefore, a period where the first transistor ‘TR1’ and the second transistor ‘TR2’ are simultaneously turned on is generated, in which a data output operation is influenced by noise.

As described above, a large amount of noise might be generated when a main driver operates in semiconductor apparatuses according to the related art. Accordingly, it is difficult to ensure stability in a data output operation. Further, there is a limit in improving the data output speed while accounting for the noise generated in the main driver. As described above, semiconductor apparatuses according to the related art have a problem in that it is difficult to stably perform a data output operation at high speeds.

### SUMMARY

Aspects of the present invention include a semiconductor apparatus that implements more stable data output operation and a data output method of the semiconductor apparatus.

In one embodiment of the present invention, a semiconductor apparatus includes a driving control unit configured to receive an enable signal and a data signal and to generate a pull-up source signal and a pull-down source signal, wherein the driving control unit is configured to delay a generation timing of the pull-up source signal or the pull-down source signal; a driver configured to generate a driving data signal by driving the pull-up source signal and the pull-down source signal from the driving control unit; and a POD (Pseudo Open Drain) impedance control unit that is connected to an output terminal of the driver and has a variable resistance value.

In another embodiment of the present invention, a data output method of a semiconductor apparatus having a POD (Pseudo Open Drain) impedance control unit at an output terminal of a main driver outputting a driving data signal, includes deactivating both a pull-up part and a pull-down part of the main driver when a data output operation starts; and generating the driving data signal by selectively activating the pull-up part or the pull-down part of the main driver according to a level of a data signal received at the semiconductor apparatus.

These and other features, aspects, and embodiments are described below in the period “Detailed Description.”

### BRIEF DESCRIPTION OF THE DRAWINGS

Features, aspects, and embodiments are described in conjunction with the attached drawings, in which:

FIG. 1 is a diagram schematically showing an SSTL type interface;

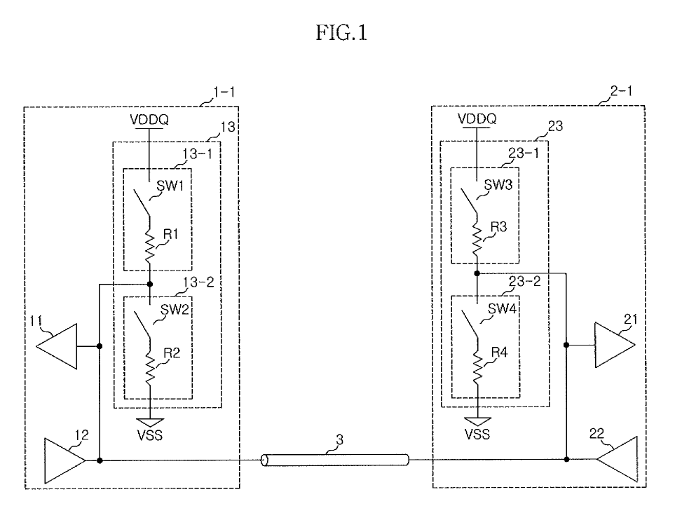

FIG. 2 is a diagram schematically showing a POD type interface;

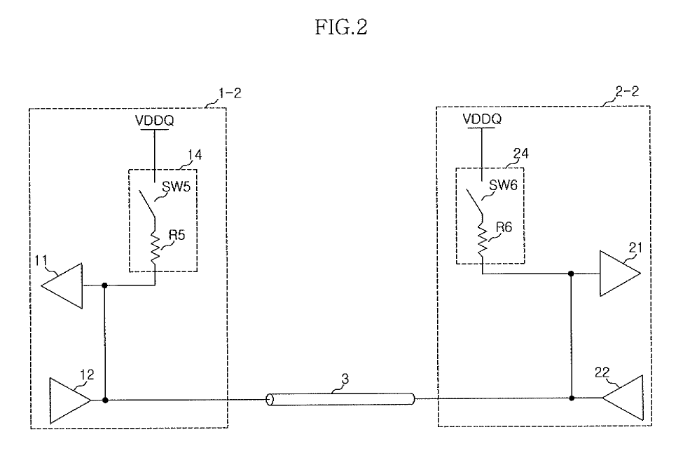

FIG. 3 is a diagram schematically showing a configuration of a main driver provided in an output buffer of the semiconductor memory apparatuses of FIG. 1 and FIG. 2;

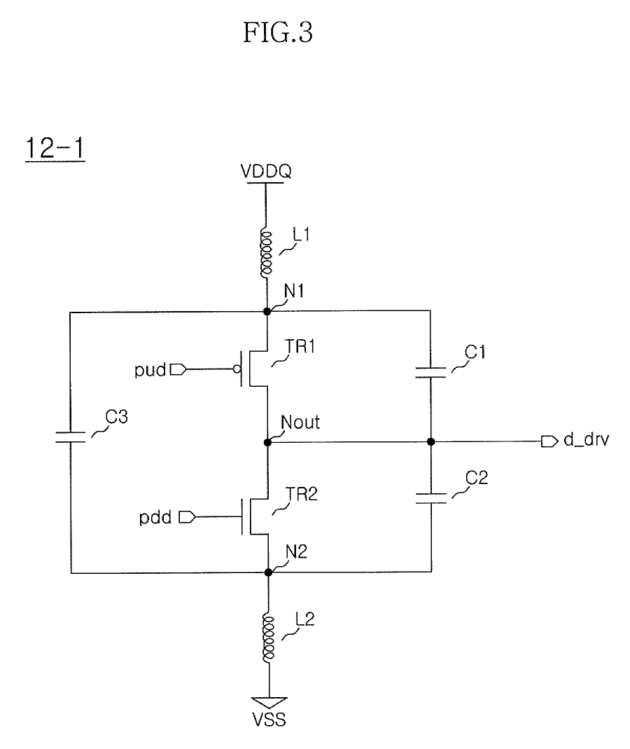

FIG. 4 is a diagram showing a configuration of a semiconductor apparatus according to an embodiment of the present invention;

FIG. 5 is a diagram showing a configuration of the driving control unit shown in FIG. 4; and

FIG. 6 is a timing diagram showing an operation of the semiconductor apparatus shown in FIG. 4.

FIG. 7 is a diagram showing a configuration of the main driver shown in FIG. 4.

### DETAILED DESCRIPTION

Hereinafter, preferred embodiments will be described in detail with reference to the accompanying drawings.

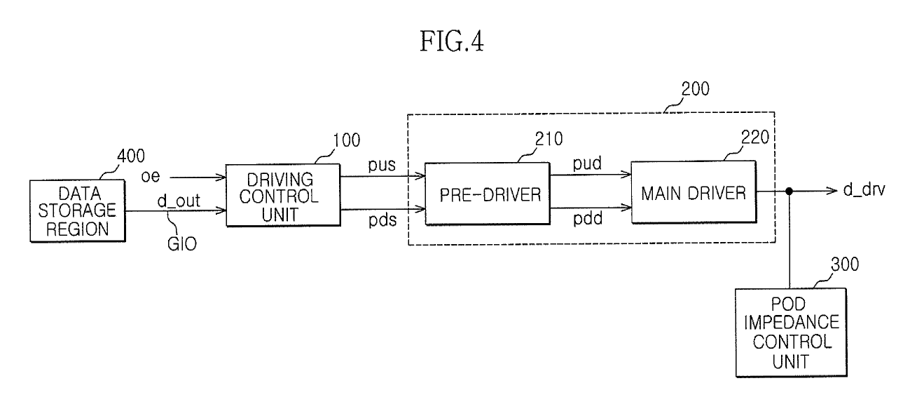

FIG. 4 is a diagram illustrating a configuration of a semiconductor apparatus according to an embodiment of the present invention, in which a data output circuit is schematically shown.

As shown in FIG. 4, a semiconductor apparatus according to an embodiment of the present invention can include a driving control unit 100, a driver 200, and a POD impedance control unit 300.

The driving control unit 100 receives an output-enable signal ‘oe’ and an output data signal ‘d_out’ and generates a pull-up source signal ‘pus’ and a pull-down source signal ‘pds’. The driver 200 generates a driving data signal ‘d_drv’ by driving the pull-up source signal ‘pus’ and the pull-down source signal ‘pds’. The POD impedance control unit 300 is connected to an output terminal of the driver 200 and has a variable resistance value.

The output data signal ‘d_out’ is a data signal transmitted from a data storage region 400 through a global line ‘GIO’, which is a data signal having continuous plural bits. The output-enable signal ‘oe’ is a signal setting a driving period of the output data signal ‘d_out’. The driving control unit 100 allows only predetermined bits of the output data signal ‘d_out’ to be driven by generating the pull-up source signal ‘pus’ and the pull-down source signal ‘pds’ from the output data signal ‘d_out’ while in an enable period of the output-enable signal ‘oe’.

During this operation, the driving control unit 100 delays the generation timing of the pull-up source signal ‘pus’ or the pull-down source signal ‘pds’ according to the level of the output data signal ‘d_out’. That is, while the output-enable signal ‘oe’ is enabled and the level of the output data signal ‘d_out’ is at a first level (high level herein), the driving control unit 100 first generates the pull-down source signal ‘pds’ and then generates the pull-up source signal ‘pus’ by delaying the generation timing of the pull-up source signal ‘pus’. On the contrary, when the level of the output data signal ‘d_out’ is at a second level (low level herein) and the output-enable signal ‘oe’ is enabled, the driving control unit 100 first generates the pull-up source signal ‘pus’ and then generates the pull-down source signal ‘pds’ by delaying the generation timing of the pull-down source signal ‘pds’.

The driver 200 can include a pre-driver 210 and a main driver 220.

The pre-driver 210 generates a pull-up driving signal ‘pud’ and a pull-down driving signal ‘pdd’ by driving the pull-up source signal ‘pus’ and the pull-down source signal ‘pds’ received from the driving control unit 100, respectively. The main driver 220 generates a driving data signal ‘d_drv’ according to the pull-up driving signal ‘pud’ and the pull-down driving signal ‘pdd’.

The pre-driver 210 includes a driver (not shown) that is implemented by combining an inverter with a resistance element along each path of the pull-up source signal ‘pus’ and the pull-down source signal ‘pds’. The pull-up driving signal ‘pud’ and the pull-down driving signal ‘pdd’ output from the pre-driver 210 have the same difference in generation timing as the difference between the pull-up source signal ‘pus’ and the pull-down source signal ‘pds’.

Since the generation timings of the pull-up driving signal ‘pud’ and the pull-down driving signal ‘pdd’ are different, a period is generated where both the transistor of a pull-up part and the transistor of a pull-down part inside the main driver 220 are turned off. Accordingly, a current path from the power supply terminal to the grounding terminal is not formed in the main driver 220. As a result, the prevention of noise due to inductance is achieved and thus, the stability of the data output operation of the semiconductor apparatus can be vastly improved.

Turning off the transistors of the pull-up part and the pull-down part inside the main driver 220 is possible by providing the POD impedance control unit 300 at the output terminal of the main driver 220 through which the driving data signal ‘d_drv’ is output. Whereas when using an impedance control unit for an SSTL type interface at the output terminal of the main driver 220 in place of the POD impedance control unit 300, when the transistors of the pull-up part and the pull-down part inside the main driver 220 are both turned off, the voltage level of the driving data signal ‘d_drv’ is half the external power supply voltage ‘VDDQ’, which results in distortion of the logic value of the driving data signal ‘d_drv’. This is because the impedance control unit for the SSTL type interface has the pull-up part and the pull-down part, and the node and the output terminal of the main driver are connected therebetween. However, according to an embodiment of the present invention, the POD impedance control unit 300 does not have a voltage sink path by having only the pull-up part as described above. Therefore, it is possible to achieve a stable data output operation even though the transistors of the pull-up part and the pull-down part of the main driver 220 are both turned off.

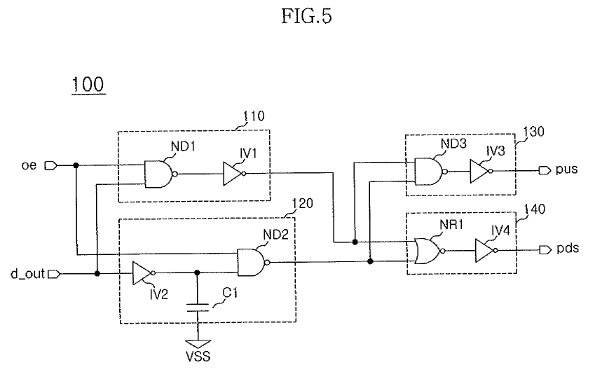

FIG. 5 is a diagram showing a configuration of the driving control unit shown in FIG. 4

As shown in the FIG. 4, the driving control unit 100 can include an enable control unit 110, a delay unit 120, a pull-up source generating unit 130, and a pull-down source generating unit 140.

The enable control unit 110 controls whether to drive the output data signal ‘d_out’ according to the output-enable signal ‘oe’. The enable control unit 110 can include a first NAND gate ‘ND1’ and a first inverter ‘IV1’.

The first NAND gate ‘ND1’ receives the output-enable signal ‘oe’ and the output data signal ‘d_out’. The first inverter ‘IV1’ receives an output signal of the first NAND gate ‘ND1’.

The delay unit 120 delays the output data signal ‘d_out’ in response to the output-enable signal ‘oe’. The delay unit 120 can include a second inverter ‘IV2’, a first capacitor ‘C1’, and a second NAND gate ‘ND2’.

The second inverter ‘IV2’ receives the output data signal ‘d_out’. The first capacitor ‘C1’ is disposed between the output terminal of the second inverter ‘IV2’ and the ground terminal. The second NAND gate ‘ND2’ receives the output-enable signal ‘oe’ and an output signal of the second inverter ‘IV2’.

The pull-up source signal generating unit 130 generates the pull-up source signal ‘pus’ by combining an output signal of the enable control unit 110 with an output signal of the delay unit 120. The pull-up source signal generating unit 130 can include a third NAND gate ‘ND3’ and a third inverter ‘IV3’.

The third NAND gate ‘ND3’ receives an output signal of the first inverter ‘IV1’ and an output signal of the second NAND gate ‘ND2’. The third inverter ‘IV3’ receives an output signal of the third NAND gate ‘ND3’ and outputs the pull-up source signal ‘pus’.

The pull-down source signal generating unit 140 generates the pull-down source signal ‘pds’ by combining an output signal of the enable control unit 110 with an output signal of the delay unit 120. The pull-down source signal generating unit 140 can include a first NOR gate ‘NR1’ and a fourth inverter ‘IV4’.

The first NOR gate ‘NR1’ receives an output signal of the first inverter ‘IV1’ and an output signal of the second NAND gate ‘ND2’. The fourth inverter ‘IV4’ receives an output signal of the first NOR gate ‘NR1’ and outputs the pull-down source signal ‘pds’.

According to this configuration shown in FIG. 5, the driving control unit 100 generates the pull-up source signal ‘pus’ and the pull-down source signal ‘pds’ by using the output data signal ‘d_out’ only when the output-enable signal ‘oe’ is enabled. The first capacitor ‘C1’ of the delay unit 120 functions as a delay element, and accordingly, an output signal of the delay unit 120 is delayed more than an output signal of the enable control unit 110.

Therefore, when the voltage level of the output data signal ‘d_out’ is at a high level, the pull-down source signal ‘pds’ transitions to a high level earlier than the pull-up source signal ‘pus’. When a delay time given to the output data signal ‘d_out’ by the delay unit 120 has passed, the pull-up source signal ‘pus’ can transition to a high level. On the contrary, when the voltage level of the output data signal ‘d_out’ is at a low level, the pull-up source signal ‘pus’ transitions to a low level earlier than the pull-down source signal ‘pds’. When the delay time given to the output data signal ‘d_out’ by the delay unit 120 has passed, the pull-down source signal ‘pds’ can transition to a low level.

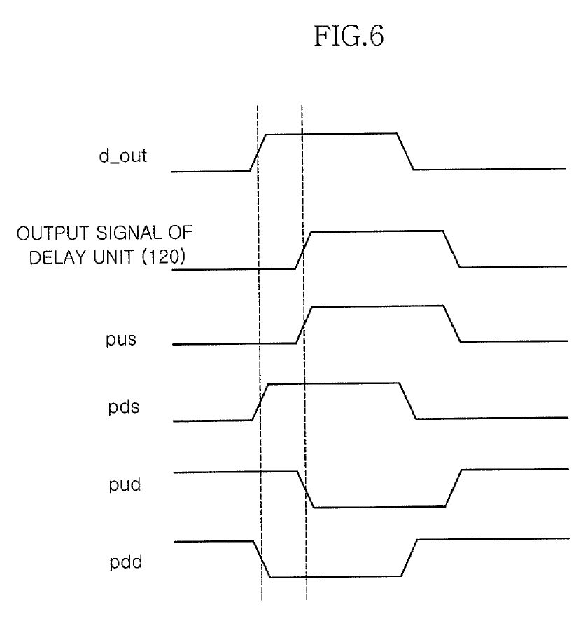

The operation of the driving control unit 100 having the above configuration as shown in FIG. 5 can be more easily understood by referring to the timing diagram of FIG. 6.

FIG. 6 is a timing diagram showing an operation of the semiconductor apparatus shown in FIG. 4. The timing diagram exemplifies when the output data signal ‘d_out’ having a logic value of 1, is input into the driving control unit 100 and an output-enable signal ‘oe’ enabled.

Referring to FIG. 6, an output signal of the delay unit 120 is delayed by a predetermined time that is greater than the output data signal ‘d_out’. However, the voltage level of the pull-down source signal ‘pds’ transitions to a high level according to the input of the output data signal ‘d_out’. Thereafter, the voltage level of the pull-up source signal ‘pus’ transitions to a high level according to the output signal of the delay unit 120. Accordingly, the pull-down driving signal ‘pdd’ transitions to a low level earlier than the pull-up driving signal ‘pud’. Thus, a period is generated where the voltage level of the pull-down driving signal ‘pdd’ is at the low level and the voltage level of the pull-up driving signal ‘pud’ is at the high level. As a result, the main driver 220 has a period where the pull-up part and the pull-down part are both turned off.

Though not shown, it is possible to determine the operation of a semiconductor apparatus when the logic value of the output data signal ‘d_out’ is 0. That is, in this case, the pull-up source signal ‘pus’ has a low voltage level earlier than the pull-down source signal ‘pds’, and accordingly the pull-up driving signal ‘pud’ has a high voltage level earlier than the pull-down driving signal ‘pdd’. Therefore, in this case as well, a period is generated where the voltage level of the pull-down driving signal ‘pdd’ is at the low level and the voltage level of the pull-up driving signal ‘pud’ is at the high level. As a result, the main driver 220 has a period where the pull-up part and the pull-down part are both turned off.

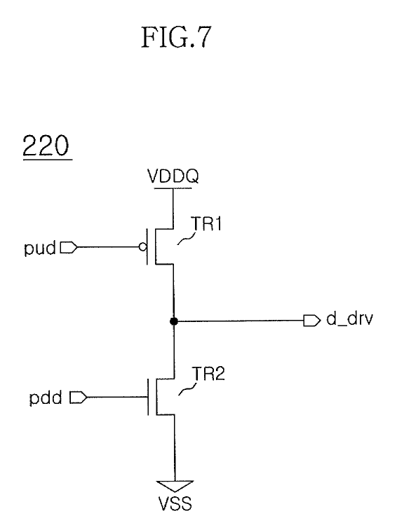

FIG. 7 is a diagram showing a configuration of the main driver shown in FIG. 4

As shown in the FIG. 4, the main driver 220 can include a first transistor TR1 and a second transistor TR2. By this configuration, the main driver 220 can generate the driving data signal ‘d_drv’ in response to the pull-up driving signal ‘pud’ and the pull-down driving signal ‘pdd’. That is, the first transistor TR1 is used as the pull-up part, and the second transistor TR2 is used as the pull-down part in the main driver 220.

As described above, a semiconductor apparatus according to an embodiment of the present invention includes an impedance control unit for a POD type interface and allows a main driver to have a period where the pull-up part and the pull-down part are both turned off in a data output operation. That is, the main driver is inactivated. According to the above configuration, it is possible to block current flowing to the grounding terminal from the power supply terminal of the main driver, and as a result, noise due to inductance formed after a package process can be prevented. By providing the impedance control unit for a POD type interface as described above, it is possible to reduce current consumption, improve the stability of the data output operation of the semiconductor apparatus by preventing noise due to inductance, and to improve the speed of the data output operation.

While certain embodiments have been described above, it will be understood that the embodiments described are by way of example only. Accordingly, the device and method described herein should not be limited based on the described embodiments. Rather, the devices and methods described herein should only be limited in light of the claims that follow when taken in conjunction with the above description and accompanying drawings.

What is claimed is:

1. A semiconductor apparatus, comprising:
a driving control unit configured to receive an enable signal and a data signal and to generate a pull-up source signal and a pull-down source signal, wherein the driving control unit is configured to delay a generation timing of the pull-up source signal or the pull-down source signal;
a driver configured to generate a driving data signal by driving the pull-up source signal and the pull-down source signal from the driving control unit; and
a POD (Pseudo Open Drain) impedance control unit that is connected to an output terminal of the driver and has a variable resistance value.

2. The semiconductor apparatus according to claim 1, wherein the driving control unit is configured to delay the generation timing of the pull-up source signal when the data signal is at a first level, and delay the generation timing of the pull-down source signal when the data signal is at a second level.

3. The semiconductor apparatus according to claim 2, wherein the driving control unit includes:
an enable control unit configured to control the driving of the data signal according to the enable signal;
a delay unit configured to delay the data signal in response to the enable signal;
a pull-up source generating unit configured to generate the pull-up source signal by combining an output signal of the enable control unit and an output signal of the delay unit; and
a pull-down source signal generating unit configured to generate the pull-down source signal by combining the output signal of the enable control unit and the output signal of the delay unit.

4. The semiconductor apparatus according to claim 1, wherein the driver includes:
a pre-driver configured to generate a pull-up driving signal and a pull-down driving signal by driving the pull-up source signal and the pull-down source signal received from the driving control unit, respectively;
a main driver configured to generate the driving data signal in response to the pull-up driving signal and the pull-down driving signal received from the pre-driver.

5. The semiconductor apparatus according to claim 4, wherein the pre-driver generates the pull-up driving signal and the pull-down driving signal by driving the pull-up source signal and the pull-down source signal and having a generation timing difference substantially equal to the generation timing difference between the pull-up source signal and the pull-down source signal.

6. The semiconductor apparatus according to claim 4, wherein the main driver has a pull-up part and a pull-down part.

7. The semiconductor apparatus according to claim 1, wherein the data signal is a signal that is transmitted through a data line from a data storage region.

8. The semiconductor apparatus according to claim 7, wherein the enable signal is a signal setting a driving period of the data signal.

9. A data output method of a semiconductor apparatus having a POD (Pseudo Open Drain) impedance control unit at an output terminal of a main driver outputting a driving data signal, comprising:
deactivating both a pull-up part and a pull-down part of the main driver when a data output operation starts; and
generating the driving data signal by selectively activating the pull-up part or the pull-down part of the main driver according to a level of a data signal received at the semiconductor apparatus.

10. The data output method of a semiconductor apparatus according to claim 9, wherein the deactivating of both the pull-up part and the pull-down part is performed by generating a pull-up driving signal for activating the pull-up part of the main driver and a pull-down driving signal for activating the pull-down part of the main driver, in response to an enable signal.

11. The data output method of a semiconductor apparatus according to claim 10, wherein the deactivating of both the pull-up part and pull-down part is performed by selectively delaying a generation timing of the pull-up driving signal or the pull-down driving signal according to the level of the data signal.

12. The data output method of a semiconductor apparatus according to claim 9, wherein the data signal is a signal that is transmitted through a data line from a data storage region.
